(19) United States
(12) Patent Application Publication
(10) Pub. No.: US 2005/0064680 A1
(43) Pub. Date: Mar. 24, 2005

(54) Device and method for bonding wafers

(76) Inventor: Erich Thallner, ST. Florian (AT)

Correspondence Address: KUSNER & JAFFE;HIGHLAND PLACE SUITE 310, 6151 WILSON MILLS ROAD, HIGHLAND HEIGHTS, OH, 44143, US

(21) Appl. No.: 10/938,931

(22) Filed: Sep. 11, 2004

(30) Foreign Application Priority Data
Sep. 24, 2003 (DE) 103 44 113.1

(51) Int. Cl. H01L 21/30

(52) U.S. Cl. 438/455

(57) ABSTRACT

The present invention relates to a device and a corresponding method for bonding wafers along their corresponding surfaces.

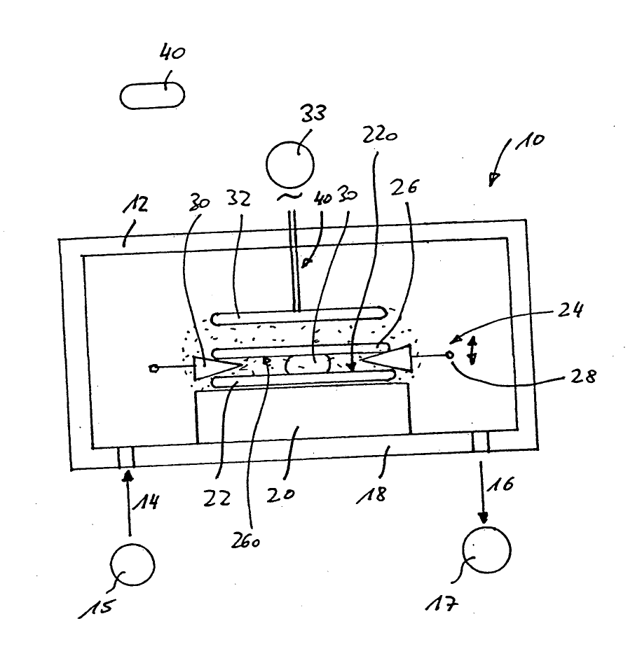

The present invention relates to a device and a method for bonding wafers.

Various methods are known for bonding wafers (wafer surfaces). The wafers may be bonded by inorganic or organic adhesives. Subjecting the wafer surfaces to plasma activation is included in the related art (U.S. Pat. No. 6,180,496 B1). This plasma activation makes the surfaces hydrophilic. The plasma activation allows bonding of the wafer surfaces with exploitation of ¢van der Waals forces”.

U.S. Pat. No. 6,180,496 B1 cited suggests the following concrete method steps: cleaning the wafer, purging and drying the cleaned wafer, positioning the wafer in the plasma chamber, plasma activating the wafer surfaces, and bonding the wafers while maintaining an uninterrupted vacuum.

An alternative device and an alternative method for bonding wafers is to be provided by the present invention.

It is essential for the related art cited that the plasma activation and the subsequent bonding be performed without interrupting the vacuum. This is referred to as “dry bonding”. However, it has been shown that the uninterrupted vacuum treatment has disadvantages. At least partial changes of the wafer surface may occur during the plasma treatment, oxidation, for example.

In the course of extensive investigations it has been shown to be advantageous to follow the plasma treatment of the wafer with a purging treatment (using an inert gas, for example), before the wafer surfaces are brought into contact with one another.

The surfaces of the wafers are activated by the plasma treatment, i.e., the surfaces are hydrophilic and the energy state of the wafer surfaces is large.

However, the heating of the surfaces by the plasma leads to an increased tendency to oxidize, particularly if it is a wafer based on silicon.

Through the purging with a purging gas such as argon, nitrogen, or the like, which follows the plasma activation according to the present invention, the tendency of the metallic wafer surface to oxidize is reduced or even prevented without impairing the surface charge.

The subsequent mechanical contacting of the wafer surfaces thus leads to optimized bonding of the wafers.

In its most general embodiment, the present invention relates to a device, for bonding wafers along their corresponding surfaces in a chamber, having the following features:
the chamber is connected in the flow of a gas purging device,
a first device is used to receive and align a first wafer,
a second device is used to receive and align a second wafer parallel to the first wafer,
the device includes a component for igniting a plasma (referred to in the following as a plasma burner) and a vacuum pump, and
a control unit, which triggers the following work steps one after another:
First, the wafers are aligned using the devices and the vacuum pump is engaged to form a vacuum in the chamber,
the plasma burner is then switched on in order to implement a plasma in the chamber via an electrode and a high frequency and cause plasma activation of the wafer surfaces. This is performed essentially at room temperatures, e.g., 10-30° C.,
in the next step, the vacuum is at least partially canceled out again by reducing the output of the vacuum pump and the gas purging device is engaged in order to conduct the purging gas over the wafers (wafer surfaces),
finally, the wafer surfaces thus plasma-activated and purged are brought together and bonded by detaching at least one of the devices or moving it in the direction toward the other device.

The first device may comprise a table-like rest like a “chuck”, for example. The table may be positioned statically or rotatably in the chamber. The first wafer may lie directly or indirectly on the rest.

The second wafer is prepared at a slight distance and parallel to the first wafer. For this purpose, a corresponding holding device may be provided in the chamber. In the simplest case, this includes a type of ring (whose diameter is larger than the wafer diameter). This ring is positioned concentrically to the wafer and has pins on the inside, for example, which are radially displaceable in order to engage and hold the second wafer punctually around its circumferential surface. The corresponding device may have its height adjusted in order to be able to set the distance to the first wafer. By disengaging the pins, the second wafer may be allowed to fall directly onto the first wafer in order to bond them to one another. The distance of the wafers during the plasma treatment is typically less than 10 mm, and it may be reduced to a distance <1 mm, even less than 500 μm.

As an alternative to the pins, the device may be implemented having at least 3 cone-like pins which are positioned at intervals to one another and radially displaceable around the circumference of and in between the wafers. Using such cones, the distance of the wafers may be adjusted in a defined way simultaneously.

The term “plasma burner” includes all devices for implementing a plasma. Details arise from U.S. Pat. No. 6,180,496 B1. According to one embodiment, the plasma burner includes an electrode which is formed by a further wafer whose material corresponds to the material of the wafers to be bonded. The identity of the materials has the advantage that contamination of the wafers to be bonded is prevented. The flat design (wafer shape) of the electrodes also has the advantage that a very uniform plasma cloud may be implemented in the chamber. The wafer surfaces may thus be activated uniformly. Therefore, the subsequent bonding is also made easier.

According to one embodiment, especially the “wafer electrode” cited, which has a high-frequency electrical field applied to it, is to be positioned parallel to the wafers to be bonded and above them. This is also shown in the following description of the figures.

In addition, all devices are made of a material which is inert in relation to the wafers, at least in the sections which come into contact with the wafers.

An associated method for bonding two wafers in a chamber has the following steps:
introducing the wafers into the chamber and aligning the wafers parallel and at a distance to one another,
evacuating the chamber,
implementing a plasma in the chamber and plasma activating the wafer surfaces to be bonded,
increasing the pressure in the chamber and purging the wafer surfaces to be bonded using a purging gas,
contacting and bonding the wafer surfaces to be bonded,
removing the bonded wafers from the chamber, possibly after performing further treatment steps.

In regard to further embodiments of the individual method steps, reference is made to the explanations above in connection with the device and the following description of the figures.

According to one embodiment, the plasma activation of the wafer surfaces is to be performed at constant pressure. In other words: the vacuum is to be kept as constant as possible.

Subsequently, the pressure is to be increased, i.e., the vacuum is at least partially canceled out again. In this case, the subsequent treatment steps, particularly the purging of the wafer surface and the bonding of the wafers, may be performed at atmospheric pressure or even at a slight excess pressure.

Further features of the present invention result from the features of the subclaims and the other documents of the application.

The present invention will be described in greater detail in the following on the basis of an exemplary embodiment. The features described therein may be significant for implementing the present invention both individually and in any arbitrary combinations. This is also true for the features which were cited above in the description of the device and the method. The single figure shows section through a device according to the present invention.

The device includes a pot-like chamber 10 having a removable cover 12, a gas supply opening 14, and a gas outlet opening 16.

A receiver 20, on which a first wafer 22 is placed, stands on a floor 18 of the chamber 10. A device 24 for receiving a second wafer 26 is provided above the wafer 22. The device 24 includes a vertically movable annular frame 28, whose internal diameter is larger than the external diameter of the wafers 22, 26 to be processed.

Three conical pins 30, shown strongly schematized here, which are radially movable (in relation to the ring 28), run on the inside from the frame 28 up into the peripheral region of the wafers 22, 26, so that they function as the spacers between the wafers 22, 26 and at the same time only provide punctual contact to the wafers 22, 26. The pins 30, which are positioned at an angle of 120° to one another, are simultaneously used for positioning the wafer 26 parallel to the wafer 22 at a defined distance (here: 2 mm).

A third wafer 32, which functions as an electrode and is connected to a high-frequency field, symbolized by ”˜”, is positioned in turn above the second wafer 26. This wafer 32 may also be positioned punctually at the edge via cones or wedges or suspended on a support (schematically indicated by 40).

The cones 30 are initially located in their outermost radial position, so that a wafer 22 may be laid on the device 20 via the open chamber 10. The pins 30 are then displaced radially inward and the second wafer 26 is loaded. Finally, the electrode 32 is positioned. The cover 12 is then closed.

A vacuum is implemented in the chamber via the opening 16 with the aid of a pump 17. In parallel or subsequently, a plasma burner 33, which includes the electrode 32, is ignited and a plasma is generated in the chamber, which leads to activation of the wafer surfaces 26o, 22o to be bonded, the plasma cloud formed being illustrated schematically by dots.

In the next step, the vacuum is interrupted and purging gas (nitrogen) is conducted into the chamber 10 by a gas purging device 15 via the opening 14. The purging treatment is thus performed under higher pressure than the plasma treatment.

After the purging procedure (the purging gas being able to escape via the opening 16), the pins 30 are moved radially outward again, so that the plasma-activated surface 26o of the wafer reaches the plasma-activated surface 22o of the wafer 22 and the two surfaces bond to one another.

If necessary, further treatment steps may follow. Otherwise, the chamber 10 is opened and the bonded wafers 22, 26 are removed.

The method steps cited are initiated and monitored by a control unit 40, which is connected to the individual device parts so it controls them.

1. A device for bonding wafers (22, 26) along their corresponding surfaces (22o, 26o) in a chamber (10), having the following features:
a. the chamber (10) is connected in the flow of a gas purging device (15),
b. a first device (20) for receiving and aligning a first wafer (22),
c. a second device (24) for receiving and aligning a second wafer (26) parallel to the first wafer (22),
d. a plasma burner (33),
e. a vacuum pump (17),
f. a control unit (40), which triggers the following work steps in sequence:
i. aligning the wafers (22, 26) using the devices (20, 24) and engaging the vacuum pump (17) to form a vacuum in the chamber (10),
ii. turning on the plasma burner (33) to form a plasma in the chamber (10) and plasma activating the wafer surfaces (22o, 26o),
iii. disengaging the vacuum pump (17) to cancel out the vacuum and engaging the gas purging device (15),
iv. bringing the corresponding wafer surfaces (22o, 26o) together and bonding them by moving at least one of the devices (24).

2. The device according to claim 1, whose first device (20) comprises a table-like rest.

3. The device according to claim 1, whose second device (24) includes at least three cone-like pins (30), which are positioned at a distance to one another and radially displaceable around the circumference of and between the wafers (22, 26).

4. The device according to claim 1, whose plasma burner (33) includes an electrode (32), which is formed by a further wafer whose material corresponds to that of the wafers (22, 26) to be bonded.

5. The device according to claim 4, whose electrode (32) is positioned parallel to the wafers (22, 26) to be bonded and above them.

6. The device according to claim 1, whose devices (20, 24), at least at the sections which come into contact with the wafers (22, 26), are made of a material which is inert in relation to the wafers (22, 26).

7. A method for bonding two wafers in a chamber, having the following steps:
a. introducing the wafers (22, 26) into the chamber (10) and aligning the wafers (22, 26) parallel and at a distance to one another,
b. evacuating the chamber (10),
c. implementing a plasma in the chamber (10) and plasma activating the wafer surfaces (22o, 26o) to be bonded,
d. increasing the pressure in the chamber (10) and purging the wafer surfaces (22o, 26o) to be bonded using a purging gas,
e. contacting and bonding the wafer surfaces (22o, 26o) to be bonded,
f. performing any further treatment steps and removing the bonded wafers (22, 26) from the chamber (10).

8. The method according to claim 7, wherein the wafer surfaces (22o, 26o) are purged using an inert gas.

9. The method according to claim 7, wherein a constant pressure is set in the chamber (10) during the plasma activation of the wafer surfaces (22o, 26o).

10. The method according to claim 7, wherein the purging of the wafer surfaces (22o, 26o) is performed at atmospheric pressure or a slight excess pressure.
